(19) United States
(12) Patent Application Publication
(10) Pub. No.: US 2026/0371979 A1
(43) Pub. Date: Nov. 19, 2026

(54) METHOD FOR MANUFACTURING A SEMICONDUCTOR CHIP

(71) Applicant: FUJI ELECTRIC CO., LTD., Kanagawa (JP)

(72) Inventor: Taketo TSUJI, Chiba-city (JP)

(21) Appl. No.: 19/653,127

(22) Filed: Apr. 21, 2026

(30) Foreign Application Priority Data
May 16, 2025 (JP) 2025-082381
Jan. 14, 2026 (JP) 2026-004088

(51) Int. Cl. H10P 58/00; H10P 72/70; H10P 74/20; H10W 46/00; H10P 52/40

(52) U.S. Cl. CPC H10P 58/00; H10P 72/7416; H10P 72/7422; H10P 74/203; H10W 46/503; H10P 52/402

(57) ABSTRACT

Provided is a method for manufacturing a plurality of semiconductor chips using a semiconductor wafer, the method comprising: forming, on an upper surface of the semiconductor wafer, an upper-surface-side structure of each of the plurality of semiconductor chips and one or more alignment structures; detecting a position of at least one alignment structure from a lower surface of the semiconductor wafer and performing lower-surface inspection of the semiconductor wafer based on the position of the alignment structure; and dicing the semiconductor wafer to singulate each semiconductor chip of the plurality of semiconductor chips.

### BACKGROUND

### 1. TECHNICAL FIELD

The present invention relates to a method for manufacturing the semiconductor chip.

### 2. RELATED ART

Patent Document 1 discloses “a method of placing a wafer on a synthetic resin film, ... and inspecting an appearance of each semiconductor chip based on an image captured by an image input apparatus in a state where the film is stretched” (Claim 1). Patent Document 2 discloses “a substrate inspection method for inspecting defects on a back surface and a surface other than the back surface of an inspection target substrate on which a plurality of patterns are formed on a front surface” (Claim 1).

Patent Document 1: Japanese Unexamined Patent Application Publication No. H8-43042.

Patent Document 2: Japanese Unexamined Patent Application Publication No. 2010-203892.

### BRIEF DESCRIPTION OF THE DRAWINGS

FIG. 1 is a diagram illustrating an example of a semiconductor wafer 10.

FIG. 2 is a top view illustrating an example of a semiconductor chip 100.

FIG. 3 is a diagram illustrating an example of the XZ cross section of the semiconductor chip 100.

FIG. 4 is a diagram for explaining a part of processes of a manufacturing method for manufacturing a plurality of semiconductor chips 100 using the semiconductor wafer 10.

FIG. 5 is a diagram illustrating an arrangement example of the alignment structure 140 observed from a lower surface 20.

FIG. 6 is a diagram illustrating the shape example of the alignment structure 140.

FIG. 7 is a diagram illustrating another shape example of the alignment structure 140.

FIG. 8 is a diagram illustrating an example of the A-A' cross section in FIG. 7.

FIG. 9 is a diagram illustrating another shape example of the alignment structure 140.

FIG. 10 is a diagram illustrating another shape example of the alignment structure 140.

FIG. 11 is a diagram illustrating an example of the B-B' cross section in FIG. 10.

FIG. 12 is a diagram illustrating another example of the B-B' cross section in FIG. 10.

FIG. 13 is a diagram illustrating the more detailed example of the manufacturing method of the semiconductor chip 100.

FIG. 14 is a diagram illustrating an example of the image 200 of the lower surface 20 of the semiconductor wafer 10.

FIG. 15 is a diagram illustrating an example of the height information of each of defect candidates 162-1, 162-2, and 162-3.

FIG. 16 is a flowchart illustrating an example of the lower-surface inspection step S408.

FIG. 17 is a diagram illustrating an example of the image 210 of the lower surface 20 of the semiconductor wafer 10.

FIG. 18 is a diagram illustrating an example of image processing on the image 210.

FIG. 19 is a diagram illustrating an example of image processing on the binarized image 210.

FIG. 20 is a diagram illustrating an example of the detection result of an inner region 166.

FIG. 21 is a flowchart illustrating an example of the lower-surface inspection step S408.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solving means of the invention.

When a term such as “same” or “equal” is used herein, it may encompass a case where an error due to a variation in manufacturing or the like is included. The error is, for example, within 10%.

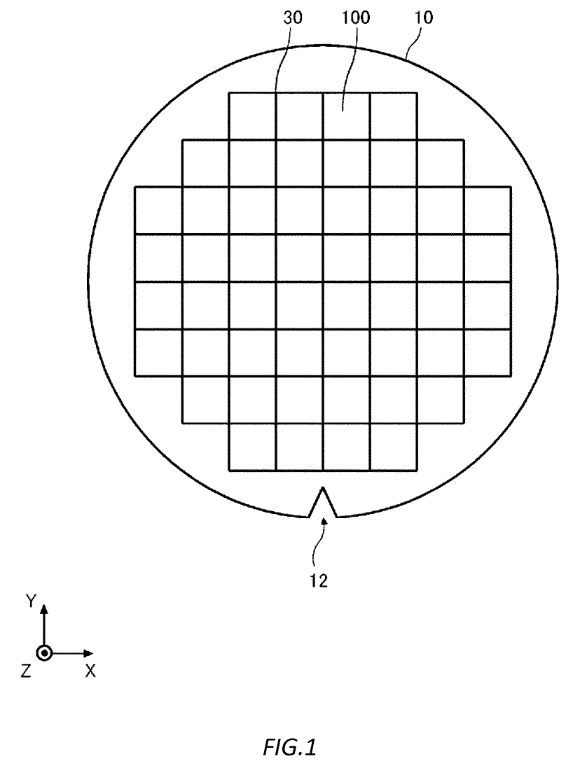

FIG. 1 is a diagram illustrating an example of the semiconductor wafer 10. The semiconductor wafer 10 is formed of a semiconductor material and has a plate shape. Although the semiconductor wafer 10 in the example of FIG. 1 has a disk shape, the shape of the semiconductor wafer 10 is not limited thereto. The semiconductor wafer 10 may be formed of a wide bandgap material having a bandgap larger than that of silicon. The semiconductor wafer 10 may be the wafer formed of SiC, GaN, AlGaN, GaAs, AlGaAs, Ga₂O₃, or diamond.

A plurality of semiconductor chips 100 are formed on the semiconductor wafer 10. A plurality of semiconductor chips 100 are formed on the plate-shaped semiconductor wafer 10 by the semiconductor process. A dicing line 30 is provided between adjacent semiconductor chips 100. Each of the semiconductor chips 100 is singulated by dicing the semiconductor wafer 10 along the dicing line 30. The semiconductor chip 100 may include, for example, a power semiconductor device such as the IGBT or the MOSFET, and may include other semiconductor devices.

In the present specification and the drawings, two orthogonal axes parallel to the upper surface of the semiconductor wafer 10 are defined as an X-axis and a Y-axis. Each dicing line 30 may be provided to extend in parallel to the X-axis or the Y-axis. In addition, the axis perpendicular to the upper surface of the semiconductor wafer 10 is defined as a Z-axis. The direction parallel to the Z-axis may be referred to as the depth direction or the height direction. The semiconductor wafer 10 may be provided with the marker 12 for detecting a rotation angle of the semiconductor wafer 10. The marker 12 of this example is the notch provided at an end portion of the semiconductor wafer 10.

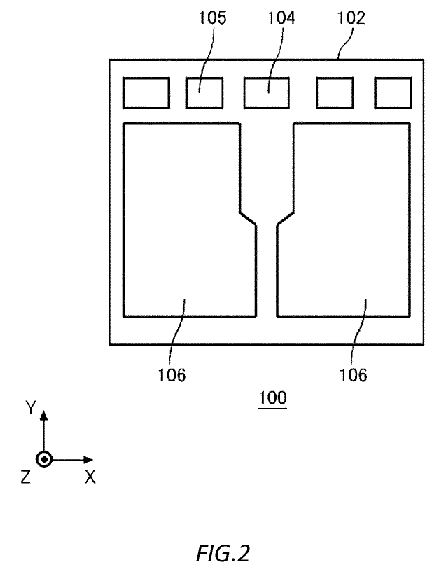

FIG. 2 is a top view illustrating an example of the semiconductor chip 100. The semiconductor chip 100 includes the semiconductor substrate 102, a pad 104, a pad 105, and a pad 106. The semiconductor substrate 102 is the substrate singulated by dicing the semiconductor wafer 10. The material of the semiconductor substrate 102 is the same as that of the semiconductor wafer 10.

The pad 104, the pad 105, and the pad 106 are an example of the upper surface electrodes provided on the upper surface of the semiconductor substrate 102. The pad 104, the pad 105, and the pad 106 may be formed of a metal such as aluminum. An insulating film is provided between a peripheral portion of the semiconductor substrate 102 and each pad, but is omitted in FIG. 2.

The pad 106 of this example is the main electrode through which a main current in the semiconductor chip 100 flows. The main current in the semiconductor chip 100 refers to, for example, the current having the largest current value among currents flowing through respective electrodes in the semiconductor chip 100. As an example, the pad 106 is an emitter electrode in an IGBT, a source electrode in a MOSFET, or an anode electrode in a diode. The pad 106 may refer to, among electrodes provided on the upper surface of the semiconductor chip 100, the electrode having the largest area.

The pad 104 and the pad 105 are electrodes through which the small current smaller than the main current flows in the semiconductor chip 100. As an example, the pad 104 is connected to the gate electrode in an IGBT or a MOSFET. The pad 105 is connected to the electrode of a sensing element that senses temperature, current, or the like, or is the electrode of the sensing element.

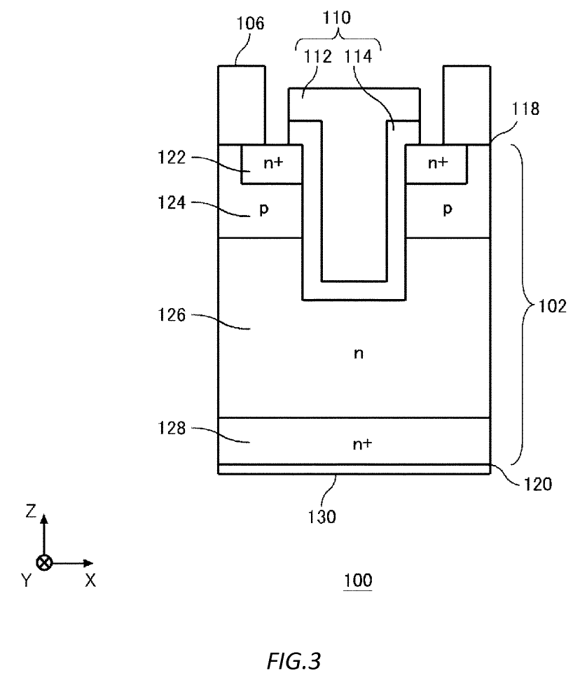

FIG. 3 is a diagram illustrating an example of the XZ cross section of the semiconductor chip 100. The semiconductor chip 100 of this example includes the MOSFET, but the semiconductor chip 100 may include other elements instead of the MOSFET, and may include other elements in addition to the MOSFET.

The semiconductor chip 100 of this example includes the semiconductor substrate 102, the pad 106, the gate structure 110, and the pad 130. The semiconductor substrate 102 has the upper surface 118 and the lower surface 120. The upper surface 118 and the lower surface 120 are two surfaces facing each other in the depth direction.

The semiconductor substrate 102 has an n-type drift region 126. The p-type base region 124 is provided between the drift region 126 and the upper surface 118. The n+-type source region 122 is provided between the base region 124 and the upper surface 118. An n+-type drain region 128 is provided between the drift region 126 and the lower surface 120.

The pad 106 is provided on the upper surface 118 of the semiconductor substrate 102. The pad 106 of this example is connected to the source region 122 and the base region 124. The pad 130, which is an example of the lower-surface electrode, is provided on the lower surface 120 of the semiconductor substrate 102. The pad 130 of this example is the drain electrode of the MOSFET. The pad 130 is connected to the drain region 128.

The gate structure 110 is provided on the upper surface 118 of the semiconductor substrate 102. The gate structure 110 has the gate electrode 112 and the gate insulating film 114. The gate structure 110 of this example is of a trench type in which at least a part of the gate electrode 112 and the gate insulating film 114 is provided inside the semiconductor substrate 102, but may be of a planar type in which the gate electrode 112 and the gate insulating film 114 are provided above the upper surface 118 of the semiconductor substrate 102.

The gate electrode 112 of this example has a portion arranged inside the semiconductor substrate 102 so as to face the base region 124. The gate electrode 112 may further have a portion facing the source region 122. The gate electrode 112 of this example is provided from the upper surface 118 of the semiconductor substrate 102 so as to pass through the source region 122 and the base region 124 and reach the drift region 126.

The gate insulating film 114 is provided between the gate electrode 112 and the semiconductor substrate 102. The gate insulating film 114 is, for example, the oxide film. The gate electrode 112 is formed of, for example, the polysilicon. When the predetermined on-voltage is applied to the gate electrode 112, the surface layer of the base region 124 facing the gate electrode 112 is inverted to the n-type, thereby forming a channel. As a result, the semiconductor chip 100 is turned on, and the main current (drain current) flows between the pad 106 and the pad 130 through the source region 122, the channel, the drift region 126, and the drain region 128. The insulating film is provided between the pad 106 and the gate structure 110, but is omitted in FIG. 3.

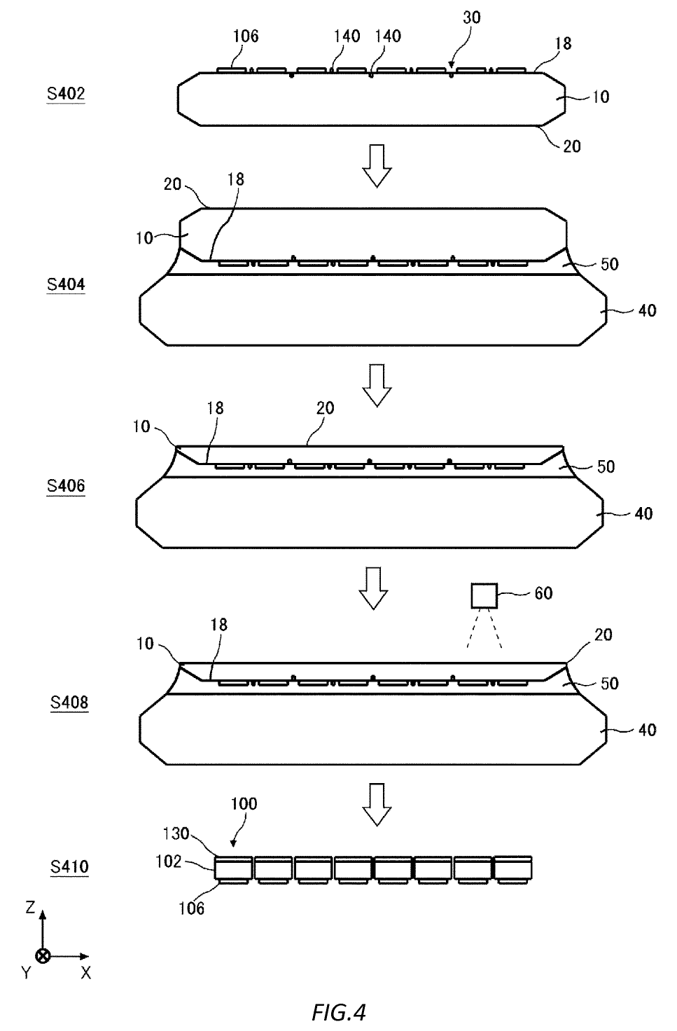

FIG. 4 is a diagram for explaining some processes of the manufacturing method for manufacturing a plurality of semiconductor chips 100 using the semiconductor wafer 10. In FIG. 4, each process is described using the cross sectional view of each member. Among the processes described in the present specification, some processes may be omitted. The semiconductor wafer 10 of this example has the upper surface 18 and the lower surface 20. The upper surface 18 corresponds to the upper surface 118 of the semiconductor substrate 102.

In the upper-surface-side formation step S402, the upper-surface-side structures of the plurality of semiconductor chips 100 and one or more alignment structures 140 are formed on the upper surface 18 of the semiconductor wafer 10. The upper-surface-side structure is the component of the semiconductor chip 100 that is provided on the upper surface 18 side of the semiconductor chip 100. The upper surface 18 side refers to the region from the center in the depth direction of the semiconductor substrate 102 to the upper surface 18. The upper-surface-side structure may include at least one of the upper surface electrode (for example, the pad 106 and the pad 104) covering at least a part of the upper surface 18 of the semiconductor wafer 10, or the gate structure 110 of a transistor device. The upper-surface-side structures of this example includes the pad 106, the pad 104, the gate structure 110, the source region 122, and the base region 124. In the example of FIG. 4, the pad 106 is shown as an example of the upper-surface-side structure.

The alignment structure 140 is the mark used, in the process of inspecting the semiconductor chip 100, to align the semiconductor wafer 10 or the semiconductor chip 100, or to identify positions of respective regions of the semiconductor chip 100. The alignment structure 140 may be an object provided so as to protrude upward from the upper surface 18 of the semiconductor wafer 10, or may be a groove (recess) provided inside the semiconductor wafer 10 from the upper surface 18. The alignment structure 140 may be a groove formed in an object provided upward from to the upper surface 18 of the semiconductor wafer 10. A substance may be filled inside the groove. The alignment structure 140 may be formed of an insulating material, or may be formed of a conductive material. The alignment structure 140 may be formed of a metal material, may be formed of polysilicon, or may be formed of a semiconductor material. In the example of FIG. 4, both types of the alignment structure 140 protruding from the upper surface 18 of the semiconductor wafer 10 and the alignment structure 140 recessed from the upper surface 18 are illustrated, but only one type of the alignment structure 140 may be provided in the semiconductor wafer 10.

At least one alignment structure 140 may be provided in the dicing line. In this case, the alignment structure 140 does not remain in each singulated semiconductor chip 100. Also, by providing some or all of the alignment structures 140 in the dicing line, the region in which semiconductor devices are formed in the semiconductor chip 100 can be secured widely.

At least one alignment structure 140 may be provided in the region in which the semiconductor chip 100 is formed. In this case, a part of the upper-surface-side structure of the semiconductor chip 100 may be used as the alignment structure 140. For example, a corner of the pad 106 may be used as the alignment structure 140. In this case, since it is not necessary to form an additional alignment structure 140, the manufacturing process of the semiconductor chip 100 can be simplified.

Next, in the protection step S404, the upper surface 18 of the semiconductor wafer 10 in which the upper-surface-side structure and the alignment structure 140 are formed is covered with the protective member 40. The protective member 40 may cover the entirety of the upper surface 18 of the semiconductor wafer 10. The protective member 40 may be formed of the insulating material. The protective member 40 may be a resist film, an oxide film, or the like, or may be glass. The protective member 40 of this example is the glass plate. The protective member 40 may be bonded to the upper surface 18 of the semiconductor wafer 10 by the insulating adhesive 50. In at least a part of the subsequent processes, processing may be performed with the protective member 40 placed on the stage.

Next, in the thinning step S406, the semiconductor wafer 10 is thinned from the lower surface 20 side of the semiconductor wafer 10, with the upper surface 18 of the semiconductor wafer 10 covered with the protective member 40. In the thinning step S406, the semiconductor wafer 10 may be thinned for the purpose of reducing resistance in the thickness direction of the substrate of the semiconductor chip 100, for example. In the thinning step S406, the semiconductor wafer 10 may be thinned by grinding using a grindstone or the like. After the grinding, polishing processing by the method such as CMP may be further performed. Also, as another thinning method, a part of the semiconductor wafer 10 may be separated by cleavage or the like. After the separation, grinding or polishing may be performed as necessary. In this example, since the upper surface 18 of the semiconductor wafer 10 is covered with the protective member 40, the upper-surface-side structure of the semiconductor wafer 10 can be protected in the thinning step S406 or the like.

The protective member 40 may be thicker in the depth direction than the semiconductor wafer 10 after thinning. The protective member 40 may be thicker than the semiconductor wafer 10 before thinning. By increasing the thickness of the protective member 40, cracking or the like of the semiconductor wafer 10 is more easily suppressed.

Next, in the lower-surface inspection step S408, a lower-surface inspection of the semiconductor wafer 10 is performed. A part of the lower-surface-side structure of the semiconductor chip 100 may be formed between the thinning step S406 and the lower-surface inspection step S408. The lower-surface-side structure is the component of the semiconductor chip 100 that is provided on the lower surface 20 side of the semiconductor chip 100. The lower surface 20 side refers to the region from the center in the depth direction of the semiconductor substrate 102 to the lower surface 20. The lower-surface-side structure may include at least a part of the pad 130 and the drain region 128. In this example, between the thinning step S406 and the lower-surface inspection step S408, the lower-surface-side structure inside the semiconductor substrate 102, such as the drain region 128, is formed. The pad 130 may be formed after the lower-surface inspection step S408.

In the lower-surface inspection step S408, a position of at least one alignment structure 140 is detected from the lower surface 20 of the semiconductor wafer 10. The processing of the lower-surface inspection step S408 may be executed by the information processing apparatus such as a computer. In the lower-surface inspection step S408, the position of the alignment structure 140 may be detected by capturing an image of a partial or an entire region of the semiconductor wafer 10 with the camera 60 from the lower surface 20 side of the semiconductor wafer 10. The camera 60 may capture an image of a region including the alignment structure 140 using the light transmitted through the semiconductor wafer 10. When the semiconductor wafer 10 is formed of a wide bandgap material, the camera 60 may capture an image of the semiconductor wafer 10 using the visible light. In this case, since visible light can be transmitted through the semiconductor wafer 10, an image of the alignment structure 140 on the upper surface 18 can be captured from the lower surface 20 of the semiconductor wafer 10.

The alignment structure 140 may be formed of a material having a higher reflectance for the imaging light than the semiconductor wafer 10. For example, at least a part of the alignment structure 140 may be formed of the metal, or may be formed of polysilicon. This makes it easier to capture an image the alignment structure 140 from the lower surface 20 side. However, the alignment structure 140 may be a step such as the groove provided in the semiconductor wafer 10. Even in such a case, an image of the alignment structure 140 including the step can be captured from the lower surface 20 side by the light transmitted through the semiconductor wafer 10.

In the lower-surface inspection step S408, the lower-surface inspection of the semiconductor wafer 10 is performed based on the position of the alignment structure 140 detected by the camera 60 or the like. For example, based on the position of the alignment structure 140, a relative position between the semiconductor wafer 10 and the camera 60 may be adjusted, and after the position adjustment, a lower-surface inspection of the semiconductor wafer 10 may be performed based on the image captured by the camera 60. The lower-surface inspection may be, for example, an inspection for presence or absence of scratches, presence or absence of adhesion of foreign matter, presence or absence of dirt, or the like on the lower surface 20 of the semiconductor wafer 10. That is, the lower-surface inspection may be the appearance inspection of the lower surface 20. In the lower-surface inspection step S408, a position of the defect may be sensed by detecting a relative position between the defect such as a detected scratch, adhesion of foreign matter, dirt, or the like and the alignment structure 140.

In the lower-surface inspection step S408, it may be determined, based on the position of the defect, in which semiconductor chip 100 the defect has occurred. In the lower-surface inspection step S408, information for identifying the position or the like of the semiconductor chip 100 in which a defect has occurred may be recorded, and the marker indicating that the defect has occurred may be attached to the semiconductor chip 100 in which the defect has occurred.

According to this example, in the lower-surface inspection step S408, the alignment structure 140 provided on the upper surface 18 can be used, and therefore positional accuracy in the lower-surface inspection can be improved. In addition, the lower surface 120 of each semiconductor chip 100 can be inspected in the wafer state. In the lower-surface inspection of a wafer, an apparatus having higher resolution than that for the lower-surface inspection of a chip is often used. For example, in lower-surface inspection of the chip, in many cases, in order to improve inspection throughput, the entirety of the pad 130 is captured in one image to sense a defect. On the other hand, in lower-surface inspection of the wafer, in many cases, the region smaller than the pad 130 is captured at a higher magnification than in the lower-surface inspection of a chip to sense a defect. As described above, in lower-surface inspection of a wafer, in many cases, the region smaller than that in the lower-surface inspection of a chip is captured, and the shape or the like of the defect can be observed with high accuracy.

Next, in the dicing step S410, the dicing line 30 of the semiconductor wafer 10 is diced to singulate each semiconductor chip 100. After the lower-surface inspection step S408 and before the dicing step S410, the pad 130 may be formed on the lower surface 20 of the semiconductor wafer 10.

By such a process, the lower-surface inspection of the semiconductor wafer 10 can be performed with high accuracy. Therefore, non-defective/defective of each semiconductor chip 100 in the semiconductor wafer 10 can be determined with high accuracy. By determining non-defective/defective of the semiconductor chip 100 with high accuracy, occurrence of defects after mounting of the semiconductor chip 100 can be suppressed.

In this example, the lower-surface inspection is performed in a state in which the upper surface 18 of the semiconductor wafer 10 is covered with the protective member 40. This makes it possible to protect the upper-surface-side structure or the like in the lower-surface inspection step S408. In addition, in this example, lower-surface inspection is performed after thinning the semiconductor wafer 10. This makes it possible to sense the defect that becomes apparent due to the thinning process.

If the lower surface 20 of the semiconductor wafer 10 has irregularities such as scratches, a through hole or irregularities may be formed in the pad 130 in some cases. The through hole or the like in the pad 130 is relatively small and is difficult to find in the inspection apparatus for the semiconductor chip 100 or in a visual appearance inspection. In contrast, in this example, since the appearance inspection of the lower surface 20 is performed before forming the pad 130, irregularities such as scratches are easy to find. In addition, by using the inspection apparatus for the semiconductor wafer 10, in some cases, an appearance inspection can be performed using an image with higher resolution.

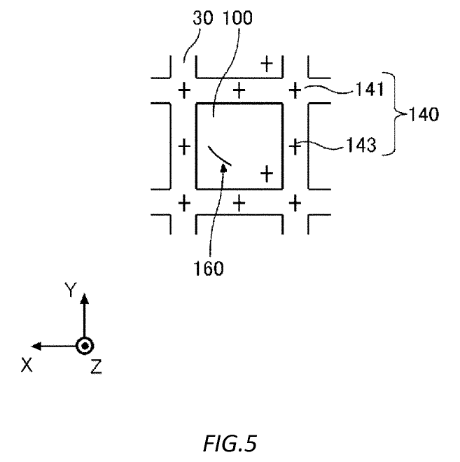

FIG. 5 is a diagram illustrating an arrangement example of the alignment structure 140 observed from the lower surface 20. In FIG. 5, the semiconductor chip 100 and the dicing line 30 are shown together. As described above, the alignment structure 140 can be observed from the lower surface 20. The alignment structure 140 may be provided in one or both of the dicing line 30 and the region of the semiconductor chip 100. A plurality of alignment structures 140 may be provided in the dicing line 30 around one semiconductor chip 100.

In lower-surface inspection, the defect 160 such as a scratch on the lower surface 20 is sensed. The position of the defect 160 within the lower surface 20 can be sensed from a relative position with respect to the alignment structure 140.

The plurality of alignment structures 140 may include the upper-surface inspection structure 141 used for upper-surface inspection of the semiconductor wafer 10 and the lower-surface inspection structure 143 used for lower-surface inspection. In upper-surface inspection of the semiconductor wafer 10, the appearance or the like of upper-surface-side structures such as the pad 104 and the pad 106 are inspected. The upper-surface inspection structure 141 is used as the alignment mark in upper-surface inspection.

The upper-surface inspection structure 141 and the lower-surface inspection structure 143 may have the same shape or structure, or may have different shapes or structures. One alignment structure 140 may function as both the upper-surface inspection structure 141 and the lower-surface inspection structure 143. That is, one alignment structure 140 may be used in both upper-surface inspection and lower-surface inspection.

The upper-surface inspection structure 141 and the lower-surface inspection structure 143 of this example have different structures. The lower-surface inspection structure 143 may have a structure that is easier to observe from the lower surface 20 than that of the upper-surface inspection structure 141.

The lower-surface inspection structure 143 may be formed of a material having a higher reflectance for visible light than the upper-surface inspection structure 141. For example, the lower-surface inspection structure 143 may be formed of metal, and the upper-surface inspection structure 141 may be formed of polysilicon or the same material as the semiconductor wafer 10. The lower-surface inspection structure 143 may be formed of polysilicon, and the upper-surface inspection structure 141 may be formed of the same material as the semiconductor wafer 10. When the lower-surface inspection structure 143 is formed of the same material as the semiconductor wafer 10, the lower-surface inspection structure 143 may be the groove formed in the upper surface 18 of the semiconductor wafer 10.

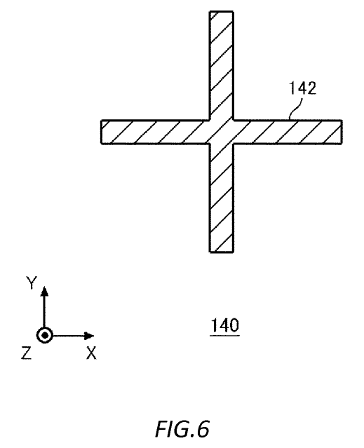

FIG. 6 is a diagram illustrating a shape example of the alignment structure 140. The alignment structure 140 of this example has a main body portion 142. The main body portion 142 may be a groove or a protrusion provided in the upper surface 18 of the semiconductor wafer 10. The main body portion 142 of this example is the groove provided in the upper surface 18 of the semiconductor wafer 10. The main body portion 142 may be an object such as metal provided on the upper surface 18.

The alignment structure 140 of this example includes the linear portion in a top view. In the example of FIG. 6, the alignment structure 140 has two linear portions extending in the respective two directions. The two linear portions may intersect.

The length of the alignment structure 140 in the XY plane may be 200 μm or less, may be 100 μm or less, may be 50 μm or less, or may be 30 μm or less. The length may be 5 μm or more, may be 10 μm or more, or may be 20 μm or more. The length may use the maximum length of the alignment structure 140 in the XY plane.

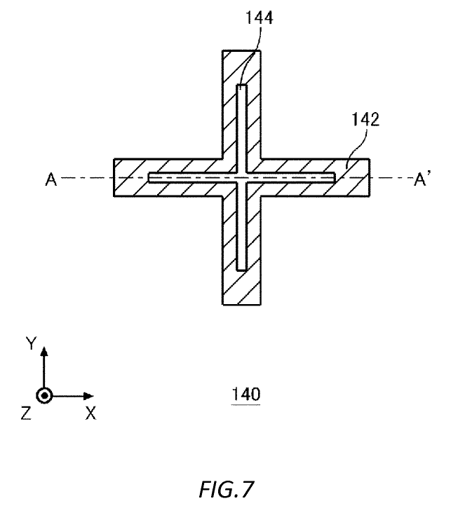

FIG. 7 is a diagram illustrating another shape example of the alignment structure 140. The alignment structure 140 of this example further includes the cutout portion 144 with respect to the configuration described in FIG. 6. The cutout portion 144 is the portion in which the main body portion 142 is not provided in a region surrounded by the main body portion 142. For example, when the main body portion 142 is a groove, the cutout portion 144 is a portion in which the groove is not provided. In this case, the upper surface 18 may remain in the cutout portion 144. When the main body portion 142 is an object such as metal, the cutout portion 144 is a portion in which the object is not provided. In this case, the upper surface 18 may be exposed in the cutout portion 144 without being covered with the object.

The cutout portion 144 of this example includes the linear portion in a top view. In the example of FIG. 6, the cutout portion 144 has two linear portions extending in respective two directions. The two linear portions may intersect. The cutout portion 144 may be provided along the main body portion 142.

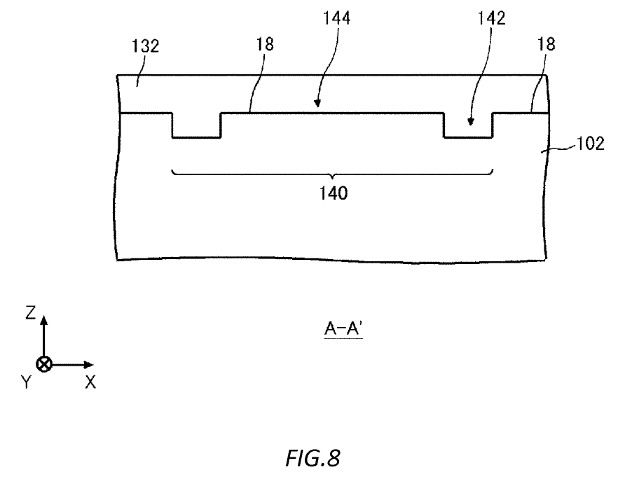

FIG. 8 is a diagram illustrating an example of the A-A' cross section in FIG. 7. The A-A' cross section is the XZ cross section passing through the main body portion 142 and the cutout portion 144. The main body portion 142 of this example is a groove provided on the upper surface 18 of the semiconductor wafer 10. In the cross section, the cutout portion 144 is sandwiched between two main body portions 142. The cutout portion 144 of this example is the upper surface 18 remaining without the main body portion 142 being formed.

The alignment structure 140 of this example is covered with the protective layer 132. The protective layer 132 is formed of an insulating material such as polyimide. When the main body portion 142 is a groove, the protective layer 132 may be filled in the interior of the main body portion 142. The main body portion 142 may be filled with metal or polysilicon instead of the protective layer 132. The upper surface of the cutout portion 144 may also be covered with the protective layer 132. The protective layer 132 may also be formed on the semiconductor chip 100. For example, the protective layer 132 may cover at least a portion of the pad 106.

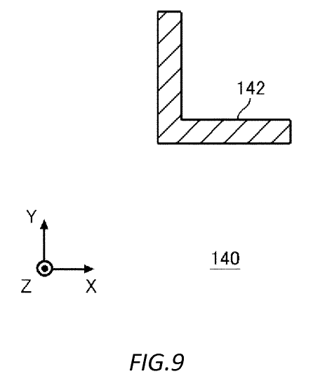

FIG. 9 is a diagram illustrating another shape example of the alignment structure 140. The main body portion 142 in the alignment structure 140 of this example has a structure in which the end portions of two linear portions are connected to each other in the XY plane. The two linear portions may be connected at the right angle. As illustrated in FIG. 9, the alignment structure 140 may have a shape that is asymmetric with respect to the predetermined direction in the XY plane. The alignment structure 140 of this example has a shape that is asymmetric in the direction parallel to the X-axis. That is, the alignment structure 140 of this example is not a shape that is line-symmetric with respect to a straight line parallel to the Y-axis.

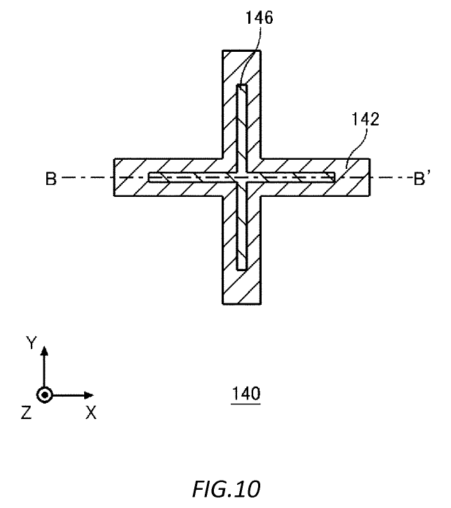

FIG. 10 is a diagram illustrating another shape example of the alignment structure 140. The alignment structure 140 of this example further includes the second main body portion 146 with respect to the configuration described in FIG. 6. The second main body portion 146 of this example is provided surrounded by the main body portion 142.

The second main body portion 146 is the groove or the protrusion provided on a bottom surface or an upper surface of the main body portion 142. For example, when the main body portion 142 is a groove, the second main body portion 146 is a groove or a protrusion provided on the bottom surface of the main body portion 142. When the main body portion 142 is a protrusion, the second main body portion 146 is a groove or a protrusion provided on the upper surface of the main body portion 142. When the second main body portion 146 is a protrusion, the second main body portion 146 may be an object such as metal, and may be a part of the semiconductor wafer 10.

The second main body portion 146 of this example includes a linear portion in a top view. In the example of FIG. 10, the second main body portion 146 has two linear portions extending in the respective two directions. The two linear portions may intersect. The second main body portion 146 may be provided along the main body portion 142.

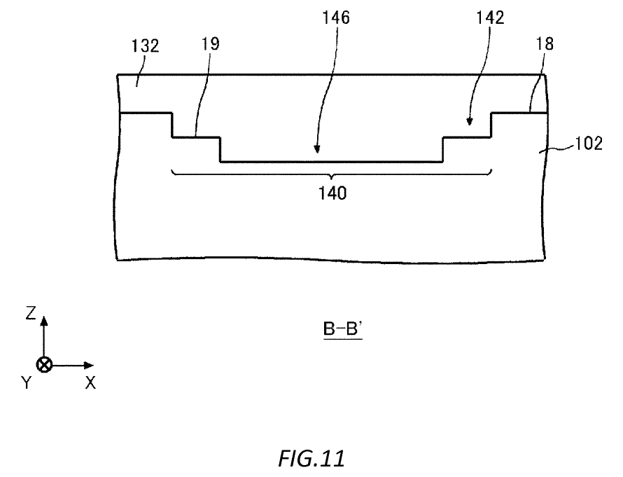

FIG. 11 is a diagram illustrating an example of the B-B' cross section in FIG. 10. The B-B' cross section is the XZ cross section passing through the main body portion 142 and the second main body portion 146. The main body portion 142 of this example is the groove provided on the upper surface 18 of the semiconductor wafer 10. In the cross section, the second main body portion 146 is sandwiched between two bottom surfaces 19 of the main body portion 142. The second main body portion 146 of this example is a groove provided on the bottom surface 19 of the main body portion 142.

The alignment structure 140 of this example is covered with the protective layer 132. The protective layer 132 is formed of an insulating material such as polyimide. When the main body portion 142 is a groove, the protective layer 132 may be filled in the interior of the main body portion 142. When the second main body portion 146 is a groove, the protective layer 132 may also be filled in the second main body portion 146. The main body portion 142 and the second main body portion 146 may be filled with metal or polysilicon instead of the protective layer 132.

In a structure in which polysilicon is filled into the alignment structure 140, an oxide film of the semiconductor wafer 10 may be provided between the polysilicon and the semiconductor wafer 10. By providing the oxide film, the adhesiveness between the semiconductor wafer 10 and the polysilicon can be improved.

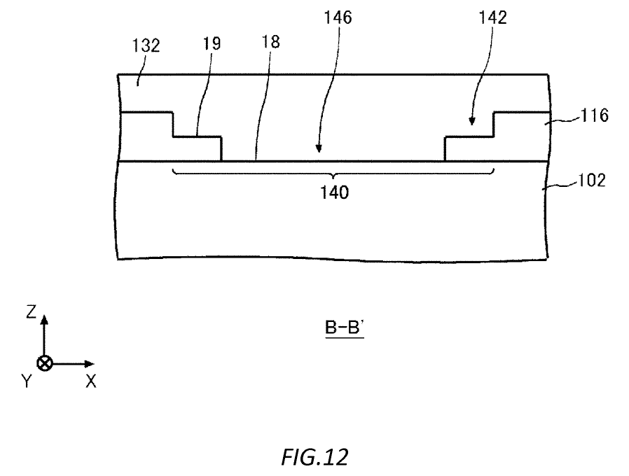

FIG. 12 is a diagram illustrating another example of the B-B' cross section in FIG. 10. The alignment structure 140 of this example is formed in the layer 116 provided on the upper surface 18 of the semiconductor wafer 10. The shape of the alignment structure 140 may be the same as that of the example of FIG. 11. The layer 116 is, for example, an insulating film such as BPSG. The layer 116 may also be formed in the semiconductor chip 100. For example, the layer 116 may be provided between the pad 106 and the semiconductor substrate 102.

The main body portion 142 of this example is the groove provided in the layer 116. The second main body portion 146 of this example is the groove provided in the bottom surface 19 of the main body portion 142. The bottom surface of the second main body portion 146 may be the upper surface 18 of the semiconductor wafer 10.

As described with reference to FIG. 5, the plurality of alignment structures 140 may include the upper-surface inspection structure 141 and the lower-surface inspection structure 143. The lower-surface inspection structure 143 may be formed deeper toward the lower surface 20 of the semiconductor wafer 10 than the upper-surface inspection structure 141. For example, the lower-surface inspection structure 143 may include, as described with reference to FIG. 11, the lower-surface-inspection groove formed from the upper surface 18 of the semiconductor wafer 10 into the inside of the semiconductor wafer 10. In this case, the main body portion 142 and the second main body portion 146 in FIG. 11 correspond to the lower-surface-inspection groove. The main body portion 142 is an example of the upper portion provided on the upper surface 18 of the semiconductor wafer 10. The second main body portion 146 is an example of the lower portion provided in a part of the bottom surface of the upper portion.

The upper-surface inspection structure 141 may include the main body portion 142 and not need to include the second main body portion 146. The upper-surface inspection structure 141 may have, for example, the structure described with reference to FIGS. 6 to 9. The main body portion 142 of the upper-surface inspection structure 141 may be the groove having the same depth as the main body portion 142 of the lower-surface inspection structure 143.

By forming the lower-surface inspection structure 143 deeply, the position of the lower-surface inspection structure 143 can be sensed with high accuracy in the lower-surface inspection step S408 (see FIG. 4). Thus, the lower-surface inspection step S408 can be performed with high accuracy.

The size of the lower-surface inspection structure 143 in the Z-axis direction may be 2 μm or more, may be 5 μm or more, may be 10 μm or more, may be 20 μm or more, or may be 30 μm or more. This size refers to the maximum value of irregularity of the lower-surface inspection structure 143 in the Z-axis direction. The size of the lower-surface inspection structure 143 in the Z-axis direction may be 100 μm or less. The size of the upper-surface inspection structure 141 in the Z-axis direction may be 50 μm or less.

The lower end of the lower-surface inspection structure 143 in the Z-axis direction may be disposed deeper than the lower end of the gate structure 110 with respect to the upper surface 18. In this case, the lower end of the upper-surface inspection structure 141 in the Z-axis direction may be formed at the same depth as or shallower than the lower end of the gate structure 110.

In another example, the lower end of the lower-surface inspection structure 143 in the Z-axis direction may be disposed at the same depth as the lower end of the gate structure 110. In this case, the lower end of the upper-surface inspection structure 141 in the Z-axis direction may be formed shallower than the lower end of the gate structure 110.

In the example of FIG. 11, either the main body portion 142 or the second main body portion 146 may be formed in the same process as the groove in the gate structure 110. The depth of either the main body portion 142 or the second main body portion 146 may be the same as the depth of the gate structure 110.

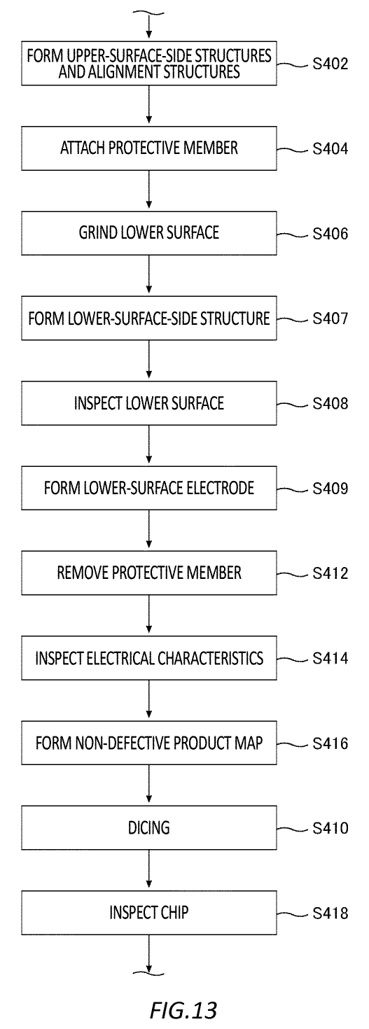

FIG. 13 is a diagram illustrating the more detailed example of the method for manufacturing the semiconductor chip 100. In the example of FIG. 13, the same reference numerals are assigned to the same processes as those in the example of FIG. 4. The upper-surface-side formation step S402, the protection step S404, and the thinning step S406 are the same as those in the example of FIG. 4.

Next, in the lower-surface-side structure formation step S407, a part of the lower-surface-side structure of the semiconductor chip 100 is formed. In the lower-surface-side structure formation step S407, for example, the drain region 128 illustrated in FIG. 3 is formed.

Next, in the lower-surface inspection step S408, lower-surface inspection of the semiconductor wafer 10 is performed based on the position of the alignment structure 140. The lower-surface inspection step S408 is the same as that in the example of FIG. 4. In the lower-surface inspection step S408, defects such as scratches, foreign matter, and irregularities on the lower surface 20 of the semiconductor wafer 10 are detected. In the lower-surface inspection step S408, non-defective/defective of each semiconductor chip 100 may be determined in accordance with the number and size of the detected defects in the XY plane and the height in the Z-axis direction.

In the lower-surface inspection step S408, the camera 60 senses the alignment structure 140, and based on the sensing result, the position and angle of the semiconductor wafer 10 in the XY plane are adjusted to perform global alignment processing of the semiconductor wafer 10. Thereafter, within each semiconductor chip 100, the position of the inspection field of view is adjusted based on the alignment structure 140 or the like. This increases the coordinate accuracy of the inspection field of view and reduces erroneous detection of defects or the like.

Since the lower surface 20 of the semiconductor wafer 10 is ground in the thinning step S406, it is relatively difficult to form the alignment structure 140 on the lower surface 20. In this example, the alignment structure 140 is formed on the upper surface 18 of the semiconductor wafer 10 and the alignment structure 140 is sensed from the lower surface 20, so that alignment accuracy in lower-surface inspection can be improved. When the semiconductor wafer 10 is formed of a wide bandgap material, the alignment structure 140 can be sensed by the visible light, so that processing is facilitated. Also, by forming at least the lower-surface inspection structure 143 with metal or polysilicon or the like, detection accuracy of the lower-surface inspection structure 143 can be further improved, and alignment accuracy can be further improved.

Next, in the lower-surface electrode formation step S409, the pad 130 is formed on the lower surface 20 of the semiconductor wafer 10. By performing lower-surface inspection before formation of the pad 130, scratches, foreign matter, or the like on the lower surface 20 of the semiconductor wafer 10 can be detected with high accuracy.

Next, in the protective member removal step S412, the protective member 40 is removed. Before removing the protective member 40, the dicing tape may be attached to the lower surface 20 of the semiconductor wafer 10. The protective member 40 may be removed in a state where the semiconductor wafer 10 is attached to the jig or the like by the dicing tape. After removing the protective member 40, the dicing tape may be removed.

Next, in the electrical characteristic inspection step S414, electrical characteristics of elements formed on the semiconductor wafer 10 are inspected. The processing of the electrical characteristic inspection step S414 may be executed by the information processing apparatus such as a computer. In the electrical characteristic inspection step S414, electrical characteristics of the semiconductor chip 100 may be measured, and electrical characteristics of the test elements such as a TEG may be measured. The test elements may be formed in the semiconductor chip 100, and may be formed outside the semiconductor chip 100. In the electrical characteristic inspection step S414, non-defective/defective of each semiconductor chip 100 may be determined based on measurement results of the electrical characteristics.

Next, in the non-defective product map formation step S416, position information of the semiconductor chip 100 in the semiconductor wafer 10 determined to be a non-defective product and the semiconductor chip 100 determined to be a defective product is registered. In the non-defective product map formation step S416, the position information may be registered in a memory or the like, or the marker indicating the position information may be formed on the semiconductor wafer 10. For example, the predetermined marker may be attached to a defective semiconductor chip 100 with ink or the like.

Next, in the dicing step S410, the semiconductor wafer 10 is diced to singulate each semiconductor chip 100. Before dicing, dicing tape may be attached to the semiconductor wafer 10.

In this example, after the lower-surface inspection step S408, the lower-surface electrode (pad 130) covering at least a part of the lower surface 20 of the semiconductor wafer 10 is formed. Then, after forming the lower-surface electrode, the semiconductor wafer 10 is diced in the dicing step S410. For this reason, the alignment structure 140 can be easily sensed in the lower-surface inspection, and the lower-surface inspection can be performed with high accuracy.

Next, in the chip inspection step S418, each singulated semiconductor chip 100 is inspected. The dicing tape may be removed before the chip inspection step S418, or may be removed after the chip inspection step S418. In the chip inspection step S418, at least one of the electrical characteristics or appearance of the semiconductor chip 100 is inspected. In the chip inspection step S418, the inspection apparatus may perform an appearance inspection based on an image captured by the camera. In the chip inspection step S418, a visual inspection of appearance by a person may be performed.

In the chip inspection step S418, each semiconductor chip 100 may be inspected based on results of the lower-surface inspection in the lower-surface inspection step S408. For example, in the chip inspection step S418, an appearance inspection on the lower surface 120 side of each semiconductor chip 100 may be performed based on results of the lower-surface inspection. For example, in the lower-surface inspection, each semiconductor chip 100 may be sorted into three-stage groups of non-defective, pending, and defective. In the lower-surface inspection, the semiconductor chip 100 in which the density, size, or the like of defects such as scratches satisfy a predetermined non-defective product criterion may be determined as a non-defective product,. In the lower-surface inspection, the semiconductor chip 100 in which the density, size, or the like of defects such as scratches are below the predetermined defective criterion may be determined as a defective product. In the lower-surface inspection, the semiconductor chip 100 that does not satisfy the non-defective product criterion but is not below the defective criterion may be determined as pending. In chip inspection step S418, by inspecting the appearance of the pending semiconductor chip 100, the semiconductor chip 100 may be determined as non-defective/defective. Accordingly, the appearance inspection of the semiconductor chip 100 can be performed efficiently and accurately.

In another example, in the lower-surface inspection, the semiconductor chips 100 may be sorted into two groups: those with a defect and those without a defect. In chip inspection step S418, the semiconductor chip 100 determined to have a defect in the lower-surface inspection may be inspected with an image of higher resolution than that of the semiconductor chip 100 determined to have no defect. Alternatively, in chip inspection step S418, the periphery of a position at which a defect such as a scratch was found in the lower-surface inspection may be inspected with an image of higher resolution than that of other portions.

In chip inspection step S418, a captured inspection image is processed to extract the defect. The inspection image may be a monochrome image, or may be a color image such as RGB. As preprocessing of the inspection image, binarization processing of the image and Fourier transform processing may be performed. When the inspection image is the color image, the inspection apparatus may extract components of respective colors such as RGB, and use a color component by which a base and a defect can be identified.

As a specific example, a case will be described in which the outermost surface of the pad 130 is gold (Au) and the defect with a concave shape (black in the image) is extracted. The gold color has the strong red component (for example, the component ratio of each color is red 255, green 215, and blue 0). On the other hand, the component ratio of each color in black is, for example, red 0, green 0, and blue 0. In such a case, by extracting the red component in the inspection image and extracting a defect, an S/N ratio (signal-to-noise ratio) can be increased, and defect extraction accuracy can be improved.

In chip inspection step S418, the inspection apparatus performs automatic determination on the image of the extracted defect. In the automatic determination, non-defective/defective determination may be performed based on a feature amount (major axis length, minor axis length, area, and aspect ratio) of the image of the extracted defect. Alternatively, non-defective/defective determination may be performed by image classification utilizing AI technology. Also in lower-surface inspection step S408, non-defective/defective determination may be performed by the same processing as that in chip inspection step S418. The defect detected by these inspection methods may be stored in the memory or the like in association with traceability information (manufacturing lot, wafer ID, and XY coordinates of the chip within the wafer) of the semiconductor chip.

Each process described in the present specification can be omitted as appropriate. For example, in the manufacturing method in one example, in upper-surface-side formation step S402, the upper-surface-side structures of a plurality of semiconductor chips 100 and one or more alignment structures 140 are formed on the upper surface 18 of the semiconductor wafer 10, in lower-surface inspection step S408, a position of at least one alignment structure 140 is detected from the lower surface 20 of the semiconductor wafer 10 and the lower-surface inspection of the semiconductor wafer 10 is performed based on the position of the alignment structure 140, and in dicing step S410, the semiconductor wafer 10 is diced to singulate each of the plurality of semiconductor chips 100. Other processes may be omitted as appropriate. In this case, since the alignment structure 140 on the upper surface 18 is observed from the lower surface 20, the lower-surface inspection can be performed accurately.

In another example manufacturing method, in the upper-surface-side formation step S402, the upper-surface-side structures of the plurality of semiconductor chips 100 are formed on the upper surface 18 of the semiconductor wafer 10, in the protection step S404, the upper surface 18 of the semiconductor wafer 10 on which the upper-surface-side structures have been formed is covered with the protective member 40, in the lower-surface inspection step S408, the lower-surface inspection of the semiconductor wafer 10 is performed in a state in which the upper surface 18 is covered with the protective member 40, and in the dicing step S410, the semiconductor wafer 10 is diced to singulate each semiconductor chip of the plurality of semiconductor chips 100. Other processing may be omitted as appropriate. In this case, the upper-surface-side structure can be protected in the lower-surface inspection or the like.

In another example manufacturing method, in the upper-surface-side formation step S402, the upper-surface-side structures of a plurality of semiconductor chips 100 are formed on the upper surface 18 of the semiconductor wafer 10, in the lower-surface inspection step S408, the lower-surface inspection of the semiconductor wafer 10 is performed, in the lower-surface electrode formation step S409, the lower-surface electrode (pad 130) covering at least a part of the lower surface 20 of the semiconductor wafer 10 is formed, and in the dicing step S410, the semiconductor wafer 10 is diced to singulate each of the plurality of semiconductor chips 100. Other processing may be omitted as appropriate. In this case, since the lower-surface inspection is performed before forming the lower-surface electrode, the defect in the lower surface 20 can be detected with high accuracy.

A defect in the lower surface 20 of the semiconductor chip 100 may cause breakage of the semiconductor chip 100. Defects in the lower surface 20 of the semiconductor chip 100 include defects derived from defects of the semiconductor substrate 102. Even if these defects are present, electrical characteristics of the semiconductor chip 100 at the time of testing may be normal, and the semiconductor chip 100 is determined to be the non-defective product in the electrical characteristic test. However, when the semiconductor chip 100 is mounted on the package or the like, the semiconductor chip 100 may be broken starting from this defect.

Such a defect may not become apparent in the process of creating the upper-surface-side structure of the semiconductor chip 100, and may become apparent due to the thinning process of the semiconductor substrate 102. Therefore, after forming the lower-surface-side structure of the semiconductor chip 100, it is preferable to detect the defect in the lower surface 20 by appearance inspection. On the other hand, in appearance inspection, pseudo defects that do not cause breakage of the semiconductor chip 100, such as contact marks with a test probe, dirt, or the like, are also extracted. If the semiconductor chip 100 including such a defect is determined to be defective, yield decreases. For this reason, in the lower-surface inspection step S408, it is preferable to detect, with high accuracy, the defect derived from a defect of the semiconductor substrate 102.

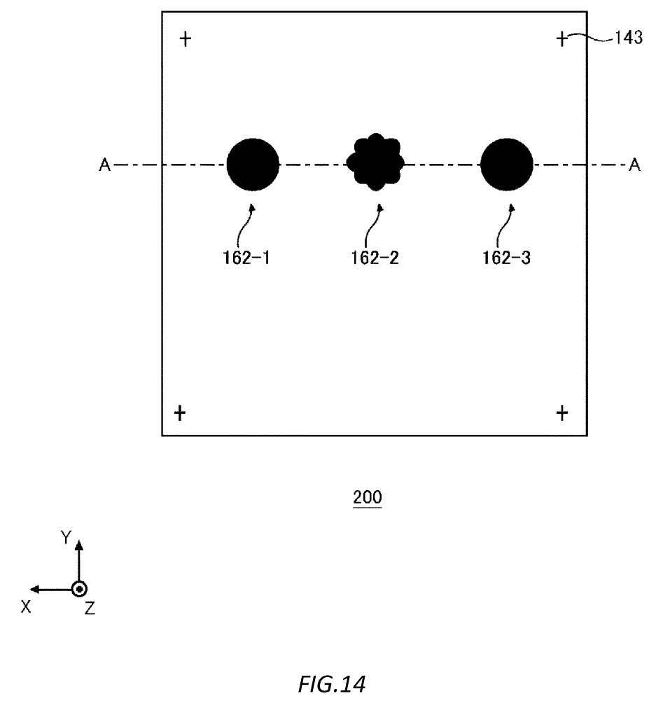

FIGS. 14-16 are diagrams for explaining an example of the lower-surface inspection step S408. In the lower-surface inspection step S408 of this example, non-defective/defective of the semiconductor chip 100 or the like is determined based on height information of the defect. By using height information of the defect, a defect that leads to breakage of the semiconductor chip 100 and a pseudo defect can be distinguished from each other.

FIG. 14 is a diagram illustrating an example of the image 200 of the lower surface 20 of the semiconductor wafer 10. In the lower-surface inspection step S408, an image 200 of the lower surface 20 of the semiconductor wafer 10 may be acquired by an imaging apparatus such as a camera. The image 200 may be an image of the partial region of the semiconductor wafer 10.

In the lower-surface inspection step S408 of this example, based on the image 200 of the lower surface 20 of the semiconductor wafer 10, a defect candidate 162 in the lower surface 20 of the semiconductor wafer 10 is extracted. In the present embodiment, the description is directed to an automatic appearance inspection apparatus that detects the defect candidate 162 in the image 200 captured by the imaging apparatus equipped with the bright-field inspection mechanism. However, the imaging apparatus may be a different imaging means such as the scanning electron microscope inspection mechanism, the dark-field inspection mechanism, a confocal inspection mechanism.

As described above, the imaging apparatus may perform alignment processing using the lower-surface inspection structure 143. For example, the imaging apparatus performs global alignment processing on the semiconductor wafer 10 to adjust the XY position and the angle in the XY plane of the semiconductor wafer 10. Thereafter, alignment is performed for each inspection field of view in the semiconductor chip 100. By using the lower-surface inspection structure 143, alignment processing can be accurately performed also in the lower-surface inspection step S408 after the thinning step S406.

The inspection apparatus may use the general pattern search algorithm as alignment processing using the lower-surface inspection structure 143. The pattern search algorithm is performed, for example, in the following steps.
1. The preset reference pattern image and the image 200 to be inspected are compressed to reduce the data amount. The pattern image may be the image of the lower-surface inspection structure 143.
2. As a first-stage search, the first region having the highest correlation value with the pattern image is detected from the image 200.
3. As the second-stage search, the second region including the first region is detected from the image 200. In the second-stage search, the compression ratio of the image is set lower (the information amount is increased) than in the first-stage search.
4. Using the uncompressed image 200, an image of the lower-surface inspection structure 143 included in the second region is detected.

Thus, the position (alignment position) of the lower-surface inspection structure 143 is determined. After determining the alignment position, the defect candidate 162 included in the image 200 is detected.

The inspection apparatus of this example may extract, as the defect candidate 162, the region having luminance different from other regions in the image 200. The defect candidate 162 may be the region having luminance smaller than other regions. In the set of pixels having luminance smaller than a predetermined luminance threshold in the image 200, a set having an area larger than a predetermined area threshold may be extracted as the defect candidate 162.

In FIG. 14, three types of defect candidates 162-1, 162-2, and 162-3 are schematically shown arranged linearly. The defect candidate 162 of this example is the region displayed in black in the image 200 (a set of pixels having small luminance).

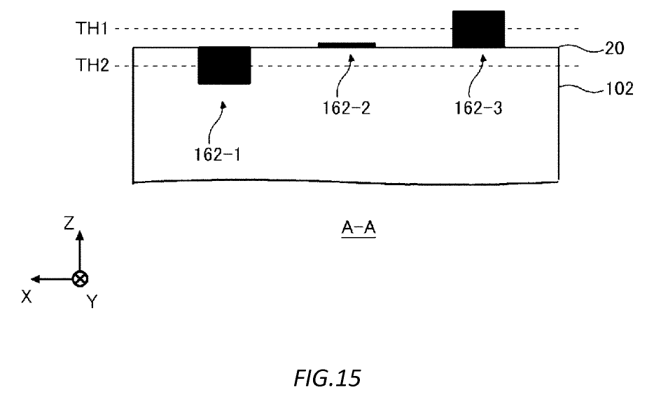

FIG. 15 is a diagram illustrating an example of the height information of each of the defect candidates 162-1, 162-2, and 162-3. In this example, the A-A cross section in FIG. 14 is illustrated. The height information of each defect candidate 162 may be a distance between the tip of the defect candidate 162 and the lower surface 20 in a Z-axis direction. The height information can be measured, for example, in the following method.
1. Using optical interference to measure the height difference of the defect candidate 162 with respect to the lower surface 20.
2. Using reflection of laser light to measure the height difference with respect to the lower surface 20.
3. Scanning the lower surface 20 with the probe to measure a height difference with respect to the lower surface 20.

A method for measuring height information may be selected depending on the state of the lower surface 20, etc.

The inspection apparatus of this example determines whether the defect candidate 162 is a defective defect based on height information of the extracted defect candidate 162. The inspection apparatus may determine whether each defect candidate 162 is a defective defect based on a comparison result between the height information of the defect candidate 162 and preset height thresholds (TH1, TH2). For example, the inspection apparatus may determine the defect candidate 162 to be a defective defect when an absolute value of height information of the defect candidate 162 is larger than the height threshold. In FIG. 15, the height threshold TH1 is a threshold in a case where the defect candidate 162 is a convex defect protruding from the lower surface 20, and the height threshold TH2 is a threshold in a case where the defect candidate 162 is a concave defect recessed in the lower surface 20. The height thresholds TH1 and TH2 may be identical to each other or may be different from each other. The height thresholds TH1 and TH2 may be preset by the inspector or the like.

In the example of FIG. 15, the defect candidate 162-1 is the concave defect in the lower surface 20 of the semiconductor substrate 102, the defect candidate 162-2 is dirt adhering to the lower surface 20 of the semiconductor substrate 102, and the defect candidate 162-3 is the convex defect in the lower surface 20 of the semiconductor substrate 102. As illustrated in FIG. 15, the defect candidate 162-1 and the defect candidate 162-3 are determined to be defective defects because the height information is larger than the height threshold. On the other hand, the defect candidate 162-2 is determined to be the pseudo defect because the height information is smaller than the height threshold. This makes it possible to prevent the pseudo defect such as dirt from being determined to be a defective defect, and to improve yield of the semiconductor chip 100.

The inspection apparatus may store information regarding the detected defective defect in association with the semiconductor chip 100. For example, the inspection apparatus may record the defective defect in association with the manufacturing lot of the semiconductor chip 100, the wafer ID, and a position or the like such as XY coordinates of the semiconductor chip 100 in the semiconductor wafer 10.

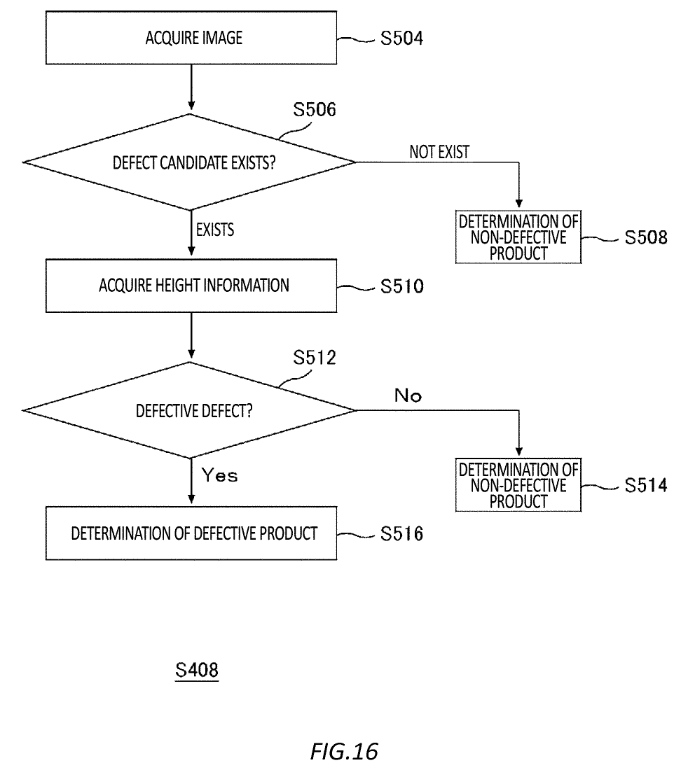

FIG. 16 is a flowchart illustrating an example of the lower-surface inspection step S408. In this example, the processing described in FIGS. 14 and 15 is performed. In the image acquisition step S504, the imaging apparatus acquires the image 200.

In the defect candidate extraction step S506, the inspection apparatus extracts the defect candidate 162 in the image 200. In the defect candidate extraction step S506, the inspection apparatus extracts, by image processing, the defect candidate 162 that satisfies a predetermined condition.

In the defect candidate extraction step S506, the inspection apparatus determines whether the defect candidate 162 exists in each semiconductor chip 100. When the defect candidate 162 does not exist, each semiconductor chip 100 is determined to be a non-defective product in the lower-surface inspection (S508). When the semiconductor chip 100 is also the non-defective product in other inspections, each semiconductor chip 100 is finally determined to be the non-defective product.

When the defect candidate 162 exists, the inspection apparatus acquires height information of each defect candidate 162 in the height information acquisition step S510. In the defect determination step S512, the inspection apparatus determines, based on the height information, whether each defect candidate 162 is either the defective defect or the pseudo defect.

When all defect candidates 162 included in one semiconductor chip 100 are pseudo defects, each semiconductor chip 100 is determined to be a non-defective product in the lower-surface inspection (S514). When the semiconductor chip 100 is also the non-defective product in other inspections, each semiconductor chip 100 is finally determined to be the non-defective product. When any defect candidate 162 is the defective defect, the corresponding semiconductor chip 100 is determined to be defective. The inspection apparatus may store information regarding the defective defect and may perform the processing from S409 (see FIG. 13) and thereafter. By such processing, it is possible to suppress the defective determination due to the pseudo defect and to improve the yield of the semiconductor chip 100.

The inspection apparatus may adjust the height threshold TH to be compared with height information of the defect candidate 162 included in the image 200, based on a detection result of the lower-surface inspection structure 143 in the image 200. For example, the inspection apparatus may adjust the height threshold TH based on an amount of blur of the image of the lower-surface inspection structure 143 included in the image 200. The image 200 may be the image acquired with focus on the lower surface 20.

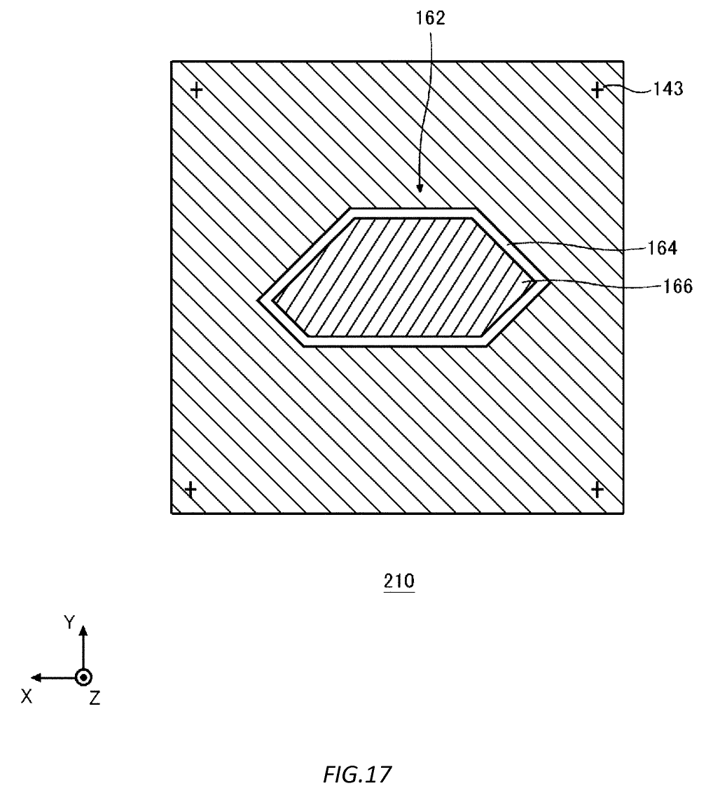

FIGS. 17-1 are diagrams for explaining another example of the lower-surface inspection step S408. In the lower-surface inspection step S408 of this example, non-defective/defective of the semiconductor chip 100 or the like is determined based on area information of the defect. By using area information of the defect, it is possible to distinguish between the defect that may lead to breakage of the semiconductor chip 100 and a pseudo defect.

FIG. 17 is a diagram illustrating an example of the image 210 of the lower surface 20 of the semiconductor wafer 10. In the lower-surface inspection step S408, the image 210 of the lower surface 20 of the semiconductor wafer 10 may be acquired by an imaging apparatus such as a camera. The image 210 may be an image of the partial region of the semiconductor wafer 10. Alignment processing in the lower-surface inspection step S408 of this example is the same as the example described in FIGS. 14-16.

In the lower-surface inspection step S408, the inspection apparatus extracts, in the image 210 of the lower surface 20 of the semiconductor wafer 10, the defect candidate 162 surrounded by the edge region 164 satisfying a predetermined luminance condition. The portion including the edge region 164 may be regarded as the defect candidate 162. In the present embodiment, the description is directed to an automatic appearance inspection apparatus that detects the defect candidate 162 in the image 210 captured by the imaging apparatus equipped with the bright-field inspection mechanism. However, the imaging apparatus may be a different imaging means such as the scanning electron microscope inspection mechanism, the dark-field inspection mechanism, a confocal inspection mechanism.

The inspection apparatus of this example detects, in the image 210, the region having luminance different from other regions as the edge region 164. The edge region 164 may be the region having higher luminance than other regions. In the image 210, among the set of pixels having luminance higher than a predetermined luminance threshold, a closed region surrounding a predetermined region like an annular shape may be detected as the edge region 164.

The inspection apparatus of this example extracts the defect that is a recess or a protrusion as the defect candidate 162. The side wall in the recess or the protrusion has a different angle at which the light is reflected, as compared with the region parallel to the lower surface 20. For example, when the image 210 is captured in a state in which the light is obliquely applied with respect to the lower surface 20, the side wall (the edge region 164) has higher luminance than other regions. The light source in this case applies the light at the plurality of types of angles. The light source may have the ring shape parallel to the lower surface 20.

By extracting the region satisfying the predetermined luminance condition, the edge region 164 of the defect that is a recess or a protrusion can be detected. A region surrounded by the edge region 164 is referred to as the inner region 166. The inner region 166 corresponds to the bottom surface of the recess defect or the upper surface of the protrusion defect.

The inspection apparatus determines whether the defect candidate 162 is the defective defect or the pseudo defect, based on area information of the inner region 166. The inspection apparatus may determine the defect candidate 162 to be a defective defect when the area of the defect candidate 162 is larger than a preset area threshold. The area threshold may be preset by the inspector or the like.

According to this example, the concave defect or the convex defect can be detected by detecting the edge region 164. Then, among the concave defect or the convex defect, one larger than the area threshold is determined as a defective defect. This makes it possible to prevent the pseudo defect such as dirt from being determined as the defective defect, and also to exclude the small defect that does not affect reliability.

The inspection apparatus may store information on the detected defective defect in association with the semiconductor chip 100. For example, the inspection apparatus may record the defective defect in association with the manufacturing lot of the semiconductor chip 100, the wafer ID, and a position or the like such as XY coordinates in the semiconductor wafer 10 of the semiconductor chip 100. In addition to the lower-surface inspection of this example, the lower-surface inspection described in FIGS. 14-16 may be further performed.

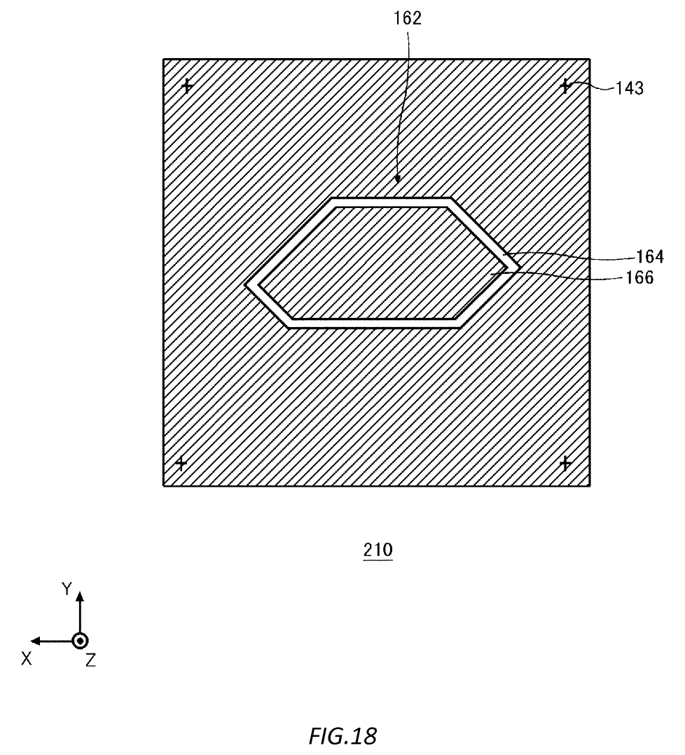

FIG. 18 is a diagram illustrating an example of image processing for the image 210. The inspection apparatus of this example binarizes the image 210. As described later, when the image 210 is the color image, the inspection apparatus may binarize the image 210 using the color component that makes it easy to identify a base and a defect. In this example, the image 210 has different pixel values between the edge region 164 and other regions.

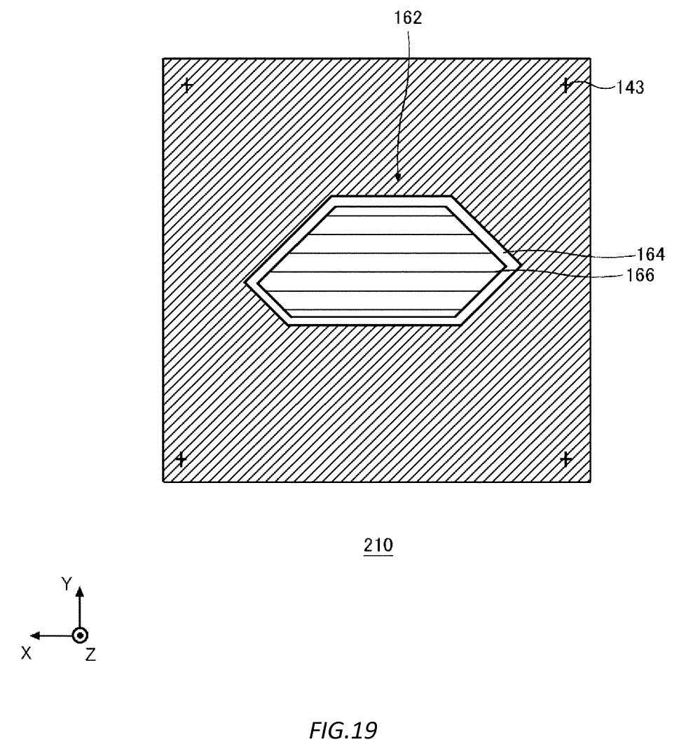

FIG. 19 is a diagram illustrating an example of image processing for the binarized image 210. The inspection apparatus extracts the edge region 164 from the binarized image 210. By binarizing the image 210, the edge region 164 becomes easier to identify. The inspection apparatus sets the pixel value of the inner region 166 surrounded by the edge region 164 to a value different from other regions. The inspection apparatus may embed the element having the same shape as the inner region 166 in the image 210.

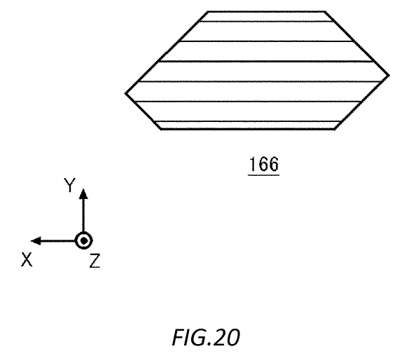

FIG. 20 is a diagram illustrating an example of the detection result of the inner region 166. The inspection apparatus detects the inner region 166 by extracting the difference between the binarized image shown in FIG. 18 and the embedded image shown in FIG. 19. The inspection apparatus may calculate the area (for example, the number of pixels) of the detected inner region 166.

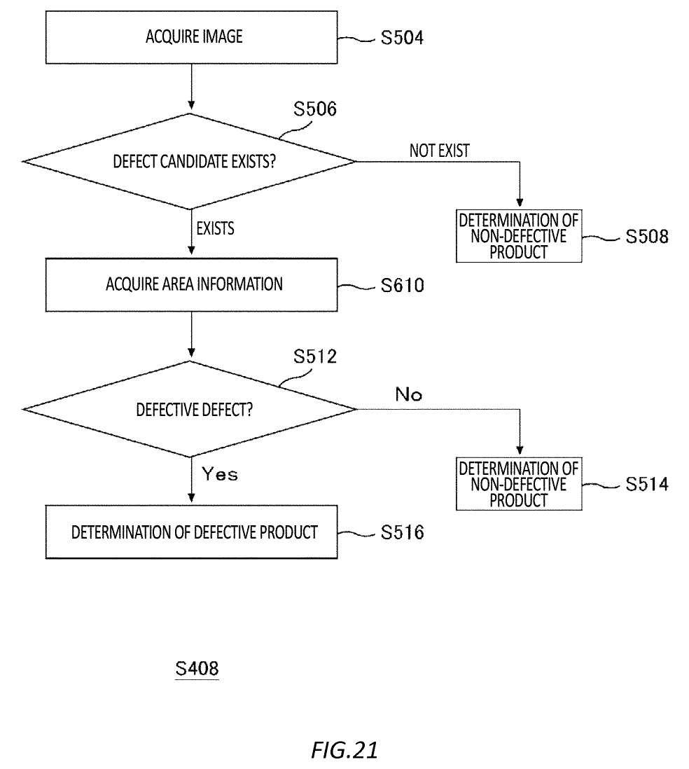

FIG. 21 is a flowchart illustrating an example of the lower-surface inspection step S408. In this example, the processing described in FIGS. 17-20 is performed. In image acquisition step S504, the imaging apparatus acquires the image 210.

In defect candidate extraction step S506, the inspection apparatus extracts the defect candidate 162 in the image 200. In defect candidate extraction step S506, the inspection apparatus extracts, by image processing, the defect candidate 162 having the edge region 164.

In the defect candidate extraction step S506, the inspection apparatus determines whether the defect candidate 162 is present in each semiconductor chip 100. When the defect candidate 162 is not present, each semiconductor chip 100 is determined to be a non-defective product in the lower-surface inspection (S508). When each semiconductor chip 100 is the non-defective product also in other inspections, each semiconductor chip 100 is finally determined to be the non-defective product.

When defect candidate 162 is present, in the area information acquisition step S610, the inspection apparatus acquires area information of each defect candidate 162. The area information may be calculated by the method described in FIGS. 18-20, or may be calculated by other methods. In defect determination step S512, the inspection apparatus determines, based on the area information, whether each defect candidate 162 is the defective defect or the pseudo defect.

When all defect candidates 162 included in one semiconductor chip 100 are pseudo defects, each semiconductor chip 100 is determined to be the non-defective product in the lower-surface inspection (S514). When each semiconductor chip 100 is the non-defective product also in other inspections, each semiconductor chip 100 is finally determined to be the non-defective product. When any defect candidate 162 is the defective defect, the corresponding semiconductor chip 100 is determined to be defective. The inspection apparatus may store information regarding the defective defect and perform the processing from S409 (see FIG. 13) and thereafter. By such processing, it is possible to suppress the defective determination due to the pseudo defect and improve the yield of semiconductor chip 100.

The inspection apparatus may adjust the area threshold to be compared with area information of defect candidate 162 included in the image 200, based on a detection result of the lower-surface inspection structure 143 in the image 200. For example, the inspection apparatus may adjust the area threshold based on the amount of blur of the image of lower-surface inspection structure 143 included in image 200. Image 200 may be the image acquired with focus on the lower surface 20.

As described above, since image 200 or the like may be compressed, lower-surface inspection structure 143 preferably has a shape that is not misrecognized even when the image is compressed. Furthermore, lower-surface inspection structure 143 preferably has a shape in which the central portion of the mark itself is easy to understand. Also for the lower-surface inspection structure 143, the oxide film or the metal film is formed during the manufacturing process. Therefore, in order to prevent occurrence of an in-film void or film peeling, the lower-surface inspection structure 143 preferably does not include a steep shape. Lower-surface inspection structure 143 may be created by the combination of a cross and a rectangle.

Image 200 may be any of the monochrome image, the grayscale image, and the color image. When extracting defect candidate 162 in image 200, the inspection apparatus may apply, as preprocessing of image 200, techniques such as the binarization processing and the Fourier transform processing. When image 200 is a color image, in performing preprocessing, color components (for example, R, G, and B) are extracted, and processing such as binarization is performed using a color component by which the base (the lower surface 20 of the semiconductor wafer 10) and a defect can be identified.

For example, it is assumed that a gold electrode is provided on the lower surface 20 of the semiconductor wafer 10, and the defect has a concave shape. In this case, the defect becomes black in image 200. The RGB values of gold color are, for example, R: 255, G: 215, and B: 0, and the red component is strong. Therefore, by performing binarization using the R component of image 200, it is possible to improve the extraction accuracy of the defect.

The inspection apparatus may automatically determine and extract the defect candidate 162 from image 200 after preprocessing. In the automatic determination, a feature amount (major axis length, minor axis length, area, and aspect ratio) of the extracted image may be used. In addition, defect candidate 162 may be extracted from two-dimensional image 200 by image classification utilizing artificial intelligence (AI) technology.

While the present invention has been described by way of the embodiments, the technical scope of the present invention is not limited to the above-described embodiments. It is apparent to persons skilled in the art that various alterations or improvements can be added to the above-described embodiments. It is also apparent from the claims that the embodiments added with such alterations or improvements can be included in the technical scope of the present invention.

The operations, procedures, steps, and stages or the like of each process performed by an apparatus, system, program, and method shown in the claims, specification, or drawings can be performed in any order as long as the order is not indicated by "prior to," "before," or the like and as long as the output from a previous process is not used in a later process. Even if the process flow is described using phrases such as "first" or "next" in the claims, specification, and drawings, it does not necessarily mean that the process must be performed in this order.

What is claimed is:

1. A method for manufacturing a plurality of semiconductor chips using a semiconductor wafer, the method comprising:
forming, on an upper surface of the semiconductor wafer, an upper-surface-side structure of each of the plurality of semiconductor chips and one or more alignment structures;
detecting a position of at least one alignment structure from a lower surface of the semiconductor wafer and performing lower-surface inspection of the semiconductor wafer based on the position of the alignment structure; and
dicing the semiconductor wafer to singulate each semiconductor chip of the plurality of semiconductor chips.

2. The method for manufacturing according to claim 1, wherein
the at least one alignment structure is provided on a dicing line.

3. The method for manufacturing according to claim 1, wherein
the at least one alignment structure is provided in a region in which the semiconductor chip is formed.

4. The method for manufacturing according to claim 1, further comprising:
covering, with a protective member, the upper surface of the semiconductor wafer on which the upper-surface-side structure and the alignment structure are formed; and
performing the lower-surface inspection in a state in which the upper surface of the semiconductor wafer is covered with the protective member.

5. The method for manufacturing according to claim 4, wherein
in a state in which the upper surface of the semiconductor wafer is covered with the protective member, the semiconductor wafer is thinned from a lower-surface side of the semiconductor wafer, and
the lower-surface inspection is performed after the semiconductor wafer is thinned.

6. The method for manufacturing according to claim 4, wherein
the upper-surface-side structure includes at least one of an upper surface electrode covering at least a part of the upper surface of the semiconductor wafer or a gate structure of a transistor device.

7. The method for manufacturing according to claim 2, further comprising:
covering, with a protective member, the upper surface of the semiconductor wafer on which the upper-surface-side structure and the alignment structure are formed; and
performing the lower-surface inspection in a state in which the upper surface of the semiconductor wafer is covered with the protective member.

8. The method for manufacturing according to claim 3, further comprising:
covering, with a protective member, the upper surface of the semiconductor wafer on which the upper-surface-side structure and the alignment structure are formed; and
performing the lower-surface inspection in a state in which the upper surface of the semiconductor wafer is covered with the protective member.

9. The method for manufacturing according to claim 1, wherein
a plurality of alignment structures include an upper-surface inspection structure used for upper-surface inspection of the semiconductor wafer and a lower-surface inspection structure used for the lower-surface inspection.

10. The method for manufacturing according to claim 9, wherein
the lower-surface inspection structure has a higher reflectance for visible light than the upper-surface inspection structure.

11. The method for manufacturing according to claim 10, wherein
the lower-surface inspection structure is formed of metal or polysilicon.

12. The method for manufacturing according to claim 9, wherein
the lower-surface inspection structure is formed deeper toward the lower surface of the semiconductor wafer than the upper-surface inspection structure.

13. The method for manufacturing according to claim 9, wherein
the lower-surface inspection structure includes a lower-surface-inspection groove formed inside the semiconductor wafer from the upper surface of the semiconductor wafer, and
the lower-surface-inspection groove includes an upper portion provided on the upper surface of the semiconductor wafer and a lower portion provided on a part of a bottom surface of the upper portion.

14. The method for manufacturing according to claim 1, wherein
the semiconductor wafer is formed of a wide bandgap material having a bandgap larger than that of silicon.

15. The method for manufacturing according to claim 1, further comprising:
after singulating the plurality of semiconductor chips, inspecting each semiconductor chip based on a result of the lower-surface inspection.

16. The method for manufacturing according to claim 1, further comprising
forming, after the lower-surface inspection, a lower-surface electrode covering at least a part of the lower surface of the semiconductor wafer; and
dicing the semiconductor wafer after forming the lower-surface electrode.

17. The method for manufacturing according to claim 1, further comprising:
in the lower-surface inspection, extracting a defect candidate in the lower surface of the semiconductor wafer based on an image of the lower surface of the semiconductor wafer; and determining whether the defect candidate is a defective defect based on height information of the defect candidate extracted.

18. The method for manufacturing according to claim 1, further comprising:
in the lower-surface inspection, extracting a defect candidate surrounded by an edge region satisfying a predetermined luminance condition in an image of the lower surface of the semiconductor wafer; and determining whether the defect candidate is a defective defect based on area information of the defect candidate extracted.

19. A method for manufacturing a plurality of semiconductor chips using a semiconductor wafer, the method comprising:
forming, on an upper surface of the semiconductor wafer, an upper-surface-side structure of each of the plurality of semiconductor chips;
covering, with a protective member, the upper surface of the semiconductor wafer on which the upper-surface-side structure is formed;
performing lower-surface inspection of the semiconductor wafer in a state in which the upper surface is covered with the protective member; and
dicing the semiconductor wafer to singulate each semiconductor chip of the plurality of semiconductor chips.

20. A method for manufacturing a plurality of semiconductor chips using a semiconductor wafer, the method comprising:
forming, on an upper surface of the semiconductor wafer, an upper-surface-side structure of each of the plurality of semiconductor chips;
performing lower-surface inspection of the semiconductor wafer;
forming, after the lower-surface inspection, a lower-surface electrode covering at least a part of a lower surface of the semiconductor wafer; and
dicing the semiconductor wafer to singulate each semiconductor chip of the plurality of semiconductor chips.
